(19) United States
(12) Patent Application Publication
(10) Pub. No.: US 2005/0218437 A1
(43) Pub. Date: Oct. 6, 2005

(54) Raw material solution, ferroelectric film, method for manufacturing ferroelectric film, piezoelectric element, piezoelectric actuator, ink jet recording head, and ink jet printer

(76) Inventors: Mayumi Ueno, Chino-shi (JP); Takeshi Kijima, Matsumoto-shi (JP); Yasuaki Hamada, Suwa-shi (JP)

Correspondence Address: HARNESS, DICKEY & PIERCE, P.L.C., P.O. BOX 828, BLOOMFIELD HILLS, MI, 48303, US

(21) Appl. No.: 11/089,431

(22) Filed: Mar. 24, 2005

(30) Foreign Application Priority Data
Mar. 26, 2004 (JP) 2004-092719
Oct. 7, 2004 (JP) 2004-295200

(51) Int. Cl. H01L 29/76

(52) U.S. Cl. 257/295

(57) ABSTRACT

By designing the structure of ferroelectric constituting elements in a raw material solution for a ferroelectric thin film, the crystallization temperature is lowered. A raw material solution forms the ferroelectric shown by a general formula of ABO₃, and includes a sol-gel raw material, and a MOD raw material having a stoichiometric composition of at least an element B that is identical with the sol-gel raw material.

### RELATED APPLICATIONS

This application claims priority to Japanese Patent Application Nos. 2004-092719 filed Mar. 26, 2004, and 2004-295200 filed Oct. 7, 2004 which are hereby expressly incorporated by reference herein in their entirety.

### BACKGROUND

1. Technical Field

The present invention relates to raw material solutions for forming ferroelectric, ferroelectric films, methods for manufacturing ferroelectric films, piezoelectric elements, piezoelectric actuators, ink jet recording heads, and ink jet printers.

2. Related Art

Ferroelectric materials including PZT are used in various applications, such as, ferroelectric memories, piezoelectric elements, infrared ray sensors, SAW devices, and the like, their research and development are actively conducted.

A chemical solution deposition (CSD: Chemical Solution Deposition Method), such as, a sol-gel method and an MOD method is known as a typical method for forming ferroelectrics. In the sol-gel method, a solution of a precursor in which a compound such as metal alkoxide is polymerized through hydrolysis and polycondensation is used. In the sol-gel method, a solution that has three-dimensional bonds of M-O-M . . . formed by hydrolysis and polycondensation of a compound is used, and therefore there are advantages in that the density of initial nucleuses generated is high and a dense film can be obtained. Also, in the metal organic decomposition (MOD: Metal Organic Decomposition Method), a solution of a stable organometallic compound such as carboxylate of a metal or the like is used. The raw material solution used by the MOD method uses a stable organometallic compound as a raw material, and this method provides advantages in that preparation and handling of the solution composition are easy. Unlike the sol-gel method that forms a complex oxide through hydrolysis and polycondensation of a compound, the MOD method forms a complex oxide by decomposing organometallic compound, which possesses organic group with large molecular weight in an oxygen atmosphere, and thus has a tendency in which the crystallization temperature is high, and crystal grains would likely become large, compared with the sol-gel method.

A ferroelectric film is formed by coating the raw material solution described above on a substrate to form a liquid film, then drying, calcinating and crystallizing the film.

Along with further device miniaturization and higher integration in recent years, mixed mounting of other types of semiconductor elements (MOS transistors) and elements including ferroelectric films, manufacturing of stacked type ferroelectric memory cells and the like are in demand. Therefore, it is desired that crystallization can be accomplished at temperatures that do not influence the other elements.

As a technology that achieves crystallization in low temperatures, Japanese laid-open patent application 2001-139313 describes a technique to lower the crystallization temperature by accelerating the phase transition from an amorphous or non-ferroelectric crystal layer to a layer of a ferroelectric phase (perovskite phase) by annealing in a reduction atmosphere. Also, there is a report indicating that the density of initial nucleuses generated is improved by pressurized annealing with oxygen, such that fine ferroelectric crystal is formed, and the crystallization temperature is lowered (Chung-Hsin L U, et. al., “Ferroelectric Lead Zirconate Thin Films Synthesized via a High-Pressure Crystallization Process”, Jpn. J. Appl. Phys., November 2002, Vol. 41, Part 1, n11B, pp 6674-78).

Japanese laid-open patent application HEI 6-305713 describes a technology to lower the perovskite crystallization temperature by adding a stabilizing agent of alkanolamine and/or β-diketonate to a raw material solution.

However, the element arrangement of a ferroelectric crystal is decided when an amorphous phase is formed before a crystallization process, and a high energy is required to control the characteristics of the ferroelectric crystal afterward, which is not practical. Moreover, it is necessary to control the orientation of perovskite crystal to obtain excellent electrical characteristics. However, in the example described above in which an improved raw material solution is used, the orientation of perovskite crystal changes depending on the crystallization temperature, and thus the control of crystal orientation at low temperatures has not yet been made possible.

It is an object of the present invention to lower the crystallization temperature by designing the structure of ferroelectric constituting elements in a raw material solution for a ferroelectric thin film, to enable manufacturing of stacked type memory cells, and mixed mounting of ferroelectric memories and CMOS circuits.

### SUMMARY

A raw material solution in accordance with the present invention pertains to a raw material solution to form ferroelectric shown by a general formula of ABO₃, and includes: a sol-gel raw material; and a MOD raw material having a stoichiometric composition of at least an element B that is identical with that of the sol-gel raw material.

In the present invention, the sol-gel raw material is a raw material including either hydrolyzate or polycondensate of a compound including at least ferroelectric constituting elements. The MOD raw material means a raw material of an organometallic compound including ferroelectric constituting elements included in an organic solvent.

According to the raw material solution of the present invention, when a ferroelectric film is formed by using this solution, the temperature necessary for crystallization can be lowered. It is believed that, because the sol-gel raw material coexists with the MOD raw material, the MOD raw material with a high degree of freedom enters polymer chains of the sol-gel raw material, such that the crystallization can be advantageously thermodynamically advanced.

The raw material solution in accordance with the present invention can assume the following embodiments.

In the raw material solution in accordance with the present invention, the content of the MOD raw material may be 10-50 mol % against the total amount of the sol-gel raw material and the MOD raw material.

In the raw material solution in accordance with the present invention, the content of the MOD raw material may be 30-40 mol % against the total amount of the sol-gel raw material and the MOD raw material.

According to the above embodiments, the crystallization temperature can be lowered, and a ferroelectric film that is exceptionally excellent in the crystal orientation and the surface morphology can be obtained.

The raw material solution in accordance with the present invention can include a material that can improve affinity between the sol-gel raw material and the MOD raw material. According to this embodiment, the easiness for the MOD raw material to enter the sol-gel material can be improved, and the crystallization can be more advantageously thermodynamically advanced.

In the raw material solution in accordance with the present invention, the material can undergo an esterification reaction with at least one of the sol-gel raw material and the MOD raw material.

In the raw material solution in accordance with the present invention, the material can be polycarboxylic acid or polycarboxylic acid ester.

According to this embodiment, for example, the MOD raw material and the sol-gel raw material may be partially bonded via polycarboxylic acid, such that the MOD raw material can be readily introduced in the network of the sol-gel raw material. In other words, the affinity between the sol-gel raw material and the MOD raw material can be improved.

The raw material solution in accordance with the present invention can include alcohols as an organic solvent.

According to this embodiment, when polycarboxylic acid ester is used as a material to improve the affinity, polycarboxylic acid can be obtained by dissociating the polycarboxylic acid ester.

The raw material solution in accordance with the present invention can have a simple perovskite structure.

In the raw material solution in accordance with the present invention, the element A comprises at least one of Pb, Ba, Mg, Ca, Sr, La and Bi, and the element B comprises at least one of Zr, Ti, Mn, Nb, Ta, V and W.

In the raw material solution in accordance with the present invention, the element A is included by 5-25 mol % in excess against the element B.

The raw material solution in accordance with the present invention can further include Si or Ge.

According to this embodiment, Si or Ge substitutes for a part of the constituting elements of the ferroelectric shown by ABO₃, and it is possible to contribute to the decrease of the crystallization temperature.

In the raw material solution in accordance with the present invention, the Si or Ge is added as an organic metal or a metal alkoxide.

According to this embodiment, Si or Ge can be more readily mixed in the raw material solution.

A ferroelectric film in accordance with the present invention is a film formed by using the raw material solution according to the present invention. For this reason, a ferroelectric film, which can be crystallized at a low temperature, whose orientation is controlled, and whose surface morphology is excellent, can be offered.

A method for manufacturing a ferroelectric film in accordance with the present invention includes: a step of coating the raw material solution according to the present invention on a substrate; a step of performing drying and calcinating; and a step of performing crystallization by a heat treatment.

In this case, the crystallization can be conducted by a rapid heat treatment at a heat elevation rate of 50° C./sec. or greater.

According to this embodiment, the orientation can be excellently controlled.

The ferroelectric film in accordance with the present invention is applied to piezoelectric elements, semiconductor elements and the like. Because the piezoelectric element in accordance with the present invention has a ferroelectric film whose orientation is controlled, the piezoelectric element can be provided with excellent piezoelectric characteristics.

### BRIEF DESCRIPTION OF THE DRAWINGS

FIG. 1 shows figures indicating polycarboxylic acid or polycarboxylic acid ester used in a raw material solution in accordance with an embodiment of the present invention.

FIG. 2 shows figures indicating polycarboxylic acid or polycarboxylic acid ester used in a raw material solution in accordance with an embodiment of the present invention.

FIG. 3 shows figures indicating polycarboxylic acid or polycarboxylic acid ester used in a raw material solution in accordance with an embodiment of the present invention.

FIG. 4 shows figures indicating polycarboxylic acid or polycarboxylic acid ester used in a raw material solution in accordance with a present embodiment of the present invention.

FIG. 5 shows a figure indicating a reaction of a substance that improves the affinity in a raw material solution in accordance with an embodiment of the present invention.

FIG. 6 shows a figure indicating a reaction of the substance that improves the affinity in the raw material solution in accordance with the embodiment of the present invention.

FIG. 7 is a graph showing the hysteresis characteristic of a ferroelectric film formed by using a raw material solution in accordance with Comparison Example.

FIGS. 8(A)-(E) show graphs showing the hysteresis characteristics of ferroelectric films formed by using raw material solutions in accordance with Embodiment Example 1.

FIGS. 9(A)-(E) show graphs showing the hysteresis characteristics of ferroelectric films formed by using raw material solutions in accordance with Embodiment Example 2.

FIGS. 10(A)-(F) show SEM images of ferroelectric films formed by using raw material solutions in accordance with Embodiment Example 2 and Comparison Example.

FIG. 11 shows X-ray diffraction patterns of ferroelectric films formed by using raw material solutions in accordance with Embodiment Example 2 and Comparison Example.

FIG. 12 compares <111> peak intensities of ferroelectric thin films in accordance with Embodiment Example and Comparison Example.

FIGS. 13(A) and (B) are views showing a semiconductor device in accordance with an embodiment of the present invention.

FIG. 14 is a view schematically showing a piezoelectric element in accordance with an embodiment of the present invention.

FIG. 15 is a view schematically showing a structure of an ink jet recording head in accordance with an embodiment of the present invention.

FIG. 16 is an exploded perspective view schematically showing an ink jet recording head in accordance with an embodiment of the present invention.

FIG. 17 is a view schematically showing a structure of an ink jet printer in accordance with an embodiment of the present invention.

### DETAILED DESCRIPTION

Examples of embodiments of the present invention are described below.

1. Raw Material Solution

A raw material solution in accordance with an embodiment of the present invention is a raw material solution to form ferroelectric shown by a general formula of ABO₃, and includes a sol-gel raw material, and a MOD raw material having a stoichiometric composition of at least an element B is identical with the sol-gel raw material.

The sol-gel raw material can be prepared as follows. For example, metal alkoxides with a composition ratio of a desired ferroelectric thin film are mixed in solvent, and subjected to hydrolysis and polycondensation. More specifically, the sol-gel raw material is prepared as follows. First, metal alkoxides whose carbon number is four or less are mixed, and subjected to hydrolysis and polycondensation. A strong M-O-M-O . . . bond is formed by hydrolysis and polycondensation. The resulting M-O-M bond has a structure similar to a perovskite structure. It is noted here that M represents a metal element (for example, Bi, Ti, La, or Pb), and O represents oxygen. Then, a solvent is added to the product obtained by hydrolysis and polycondensation to obtain a sol-gel material.

As examples of the MOD material, a polynuclear metal complex material in which constituting elements of the ferroelectric are continuously connected either directly or indirectly can be enumerated. As specific examples of the MOD material, a metal salt of a carboxylic acid can be enumerated. As examples of the carboxylic acid, acetic acid, 2-ethylhexanoic acid, and the like can be enumerated. As examples of the metal, for example, Bi, Ti, La, Pb, and the like can be enumerated. The MOD material has an M-O bond in the same manner as the sol-gel material. However, the M-O bond does not form a continuous bond as in the sol-gel material obtained by polycondensation. Moreover, the bond structure is similar to the linear structure and completely differs from the perovskite structure.

In the raw materials in accordance with embodiments of the present invention, the sol-gel material and the MOD material may be materials in which their stoichiometric compositions of at least the element B are generally the same.

In the raw material solution in accordance with the present embodiment, the MOD raw material may preferably be included by 10-50 mol % against the total amount of the sol-gel raw material and the MOD raw material, and more preferably, it may be included by 30-40 mol %. When the content of the MOD raw material is in the range between 30 and 40 mol %, the crystallization temperature can be lowered, and a ferroelectric film that has a controlled crystal orientation and is excellent in the surface morphology can be obtained.

The raw material solution in accordance with the present embodiment can include a material that can improve the affinity between the sol-gel raw material and the MOD raw material. It is noted here that the affinity means the easiness for the MOD raw material to enter the sol-gel material. By increasing the affinity between the sol-gel raw material and the MOD raw material, the crystallization can be more advantageously thermodynamically advanced.

The material that can improve the affinity can be polycarboxylic acid or polycarboxylic acid ester.

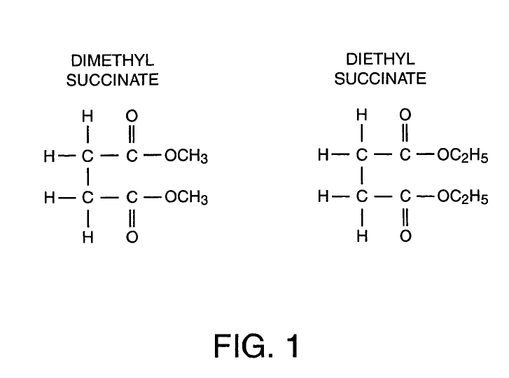

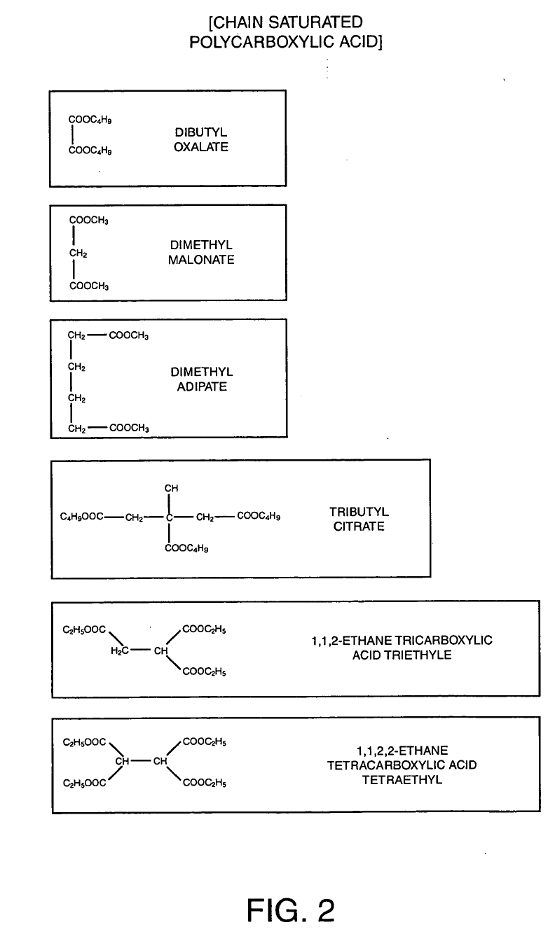

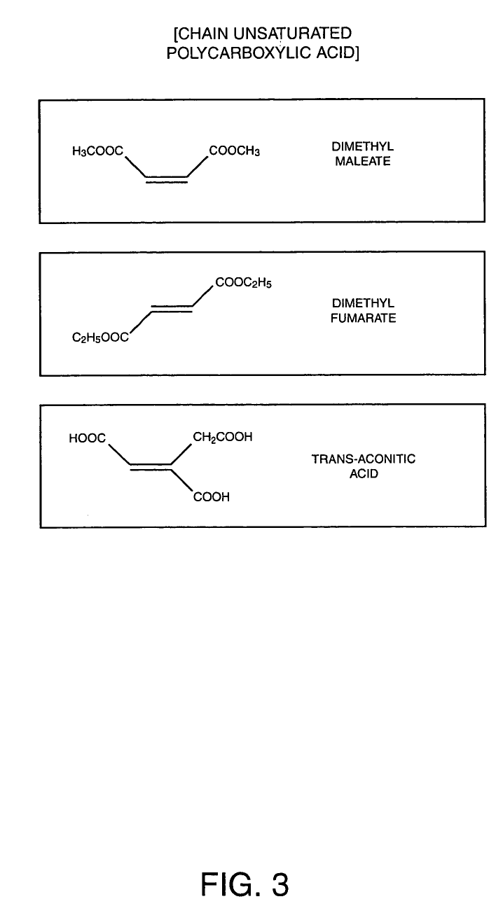

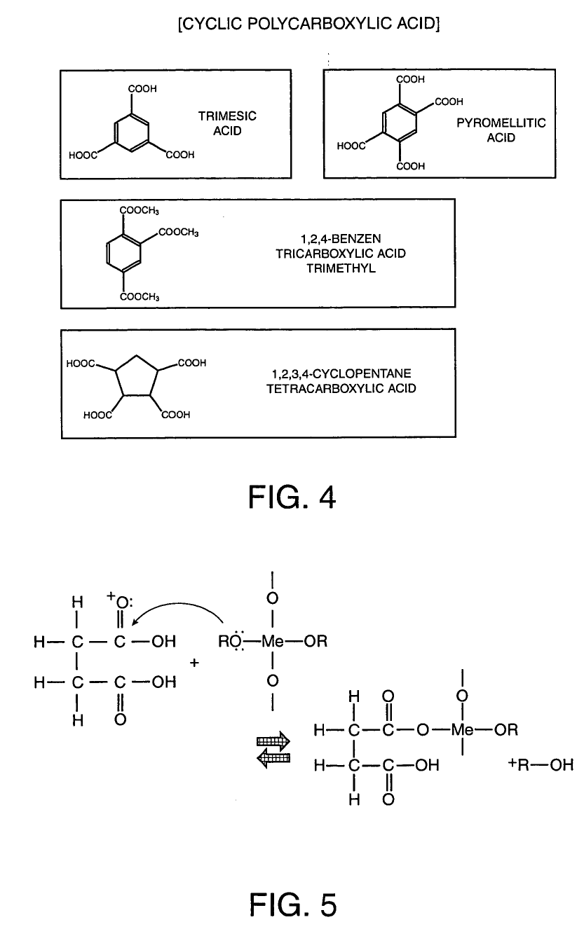

Polycarboxylic acid or polycarboxylic acid ester can have a valence of 2 or greater. As polycarboxylic acid that may be used in the present invention, the following materials can be enumerated. As polycarboxylic acid with a valence of 3, trans-aconitic acid and trimesic acid can be enumerated; and as polycarboxylic acid with a valence of 4, pyromellitic acid, 1,2,3,4-cyclopentane tetracarboxylic acid and the like can be enumerated. Moreover, as esters that dissociate in alcohol and work as polycarboxylic acid, those with a valence of 2 include dimethyl succinate, diethyl succinate, dibutyl oxalate, dimethyl malonate, dimethyl adipate, dimethyl maleate, and diethyl fumarate, those with a valence of 3 include tributyl citrate, 1,1,2-ethane tricarboxylic acid triethyle, and the like, and those with a valence of 4 include 1,1,2,2-ethane tetracarboxylic acid tetraethyl, 1,2,4-benzen tricarboxylic acid trimethyl, and the like. These polycarboxylic acid esters enumerated above dissociate in alcohol and work as polycarboxylic acid. Examples of the polycarboxylic acids or their esters are shown in FIGS. 1-4.

The polycarboxylic acid ester, in the method for manufacturing the precursor composition of the present invention, can be polycarboxylic acid ester with a valence of 2, which may preferably be at least one kind selected from ester succinate, ester maleate, and ester malonate. As concrete examples of these esters, dimethyl succinate, dimethyl maleate, and dimethyl malonate can be enumerated.

The molecular weight of the aforementioned polycarboxylic acid ester may be 150 or less. When the molecular weight of polycarboxylic acid ester is too large, the film might be damaged easily when ester volatilizes at the time of heat-treatment, and a dense film may not be obtained.

The aforementioned polycarboxylic acid ester can be a liquid in room temperature. This is because the liquid might gel if polycarboxylic acid ester is in a solid state at room temperature.

The raw material solution of the present embodiment is formed from the above-mentioned sol-gel raw material and the MOD raw material dissolved or dispersed in an organic solvent. Alcohol can be used as the organic solvent. In particular, when polycarboxylic acid ester is used, alcohol dissociates polycarboxylic acid ester, such that the action of polycarboxylic acid can be promoted.

Any alcohol can be used without any particular limitation, and buthanol, methanol, ethanol, propanol, and polyhydric alcohol can be enumerated. For example, the following can be enumerated as the alcohol.

Monovalent Alcohols:

As propanol (propyl alcohol), 1-propanol (97.4° C. in boiling point), and 2-propanol (82.7° C. in boiling point); As buthanol (butyl alcohol), 1-buthanol (117° C. in boiling point), 2-buthanol (100° C. in boiling point), 2-methyl-1-propanol (108° C. in boiling point), and 2-methyl-2-propanol (25.4° C. in melting point and 83° C. in boiling point); and

As pentanol (amyl alcohol), 1-pentanol (137° C. in boiling point),

3-methyl-1-buthanol (131° C. in boiling point), 2-methyl-1-buthanol (128° C. in boiling point), 2,2-dimetyl-1-propanol (113° C. in boiling point), 2-pentanol (119° C. in boiling point), 3-methyl-2-buthanol (112.5° C. in boiling point), 3-pentanol (117° C. in boiling point), and 2-methyl-2-buthanol (102° C. in boiling point).

Polyhydric Alcohols:

Ethylene glycol (−11.5° C. in melting point, 197.5° C. in boiling point), and glycerin (17° C. in melting point, 290° C. in boiling point).

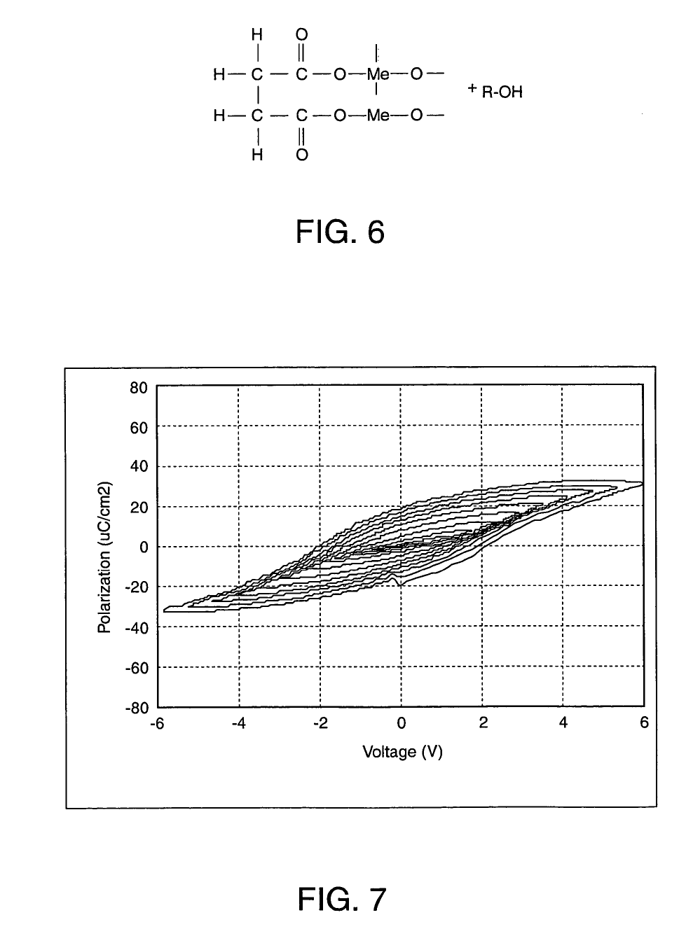

The mechanism in which the affinity increases by using polycarboxylic acid or polycarboxylic acid ester is considered as follows. First, the reaction of the sol-gel raw material with polycarboxylic acid or with polycarboxylic acid ester is considered. This reaction includes an alkoxy group substitution reaction in a first stage shown in FIG. 5, and a polymer network forming reaction by esterification in a second stage shown in FIG. 6. FIGS. 5 and 6 show an example in which dimethyl succinate is used expediently as polycarboxylic acid ester, and n-buthanol is used as an organic solvent. Dimethyl succinate is non-polarity, but dissociates in alcohol and becomes polycarboxylic acid.

In the reaction in the first stage, as shown in FIG. 5, by esterification of dimethyl succinate and metal alkoxide of the sol-gel raw material, they are ester-bonded together. More specifically, dimethyl succinate dissociates in n-buthanol, and becomes to have a state in which proton is added to one of carbonyl groups (the first carbonyl group). A substitution reaction of the alkoxy group of the metal alkoxide with the first carbonyl group occurs, and a reaction product in which the first carboxyl group is esterified and alcohol are generated. It is noted here that the “ester-bond” means a bond between a carbonyl group and an oxygen atom (—COO—).

In the reaction in the second stage, as shown in FIG. 6, a substitution reaction of the alkoxy group of the metal alkoxide with the other carboxyl group that remains in the reaction in the first step (the second carboxyl group) occurs, and a reaction product in which the second carboxyl group is esterified and alcohol are generated.

In this manner, by the reactions in two stages, a polymer network in which hydrolysis-condensation products of the metal alkoxides included in the sol-gel raw material are mutually ester-bonded is obtained. Therefore, this polymer network has ester-bonds in the network in a moderately orderly fashion. It is noted that dimethyl succinate dissociates in two stages, and the first carboxyl group has an acid dissociation constant that is larger than that of the second carboxyl group, such that the reaction in the first stage has a reaction rate greater than the reaction in the second stage. Accordingly, the reaction in the second stage advances more slowly than the reaction in the first stage.

Next, the reaction of the MOD raw material and the polycarboxylic acid is described. The active carbonyl group of the polycarboxylic acid appended with proton in alcohol forms a complex with the organic metal compound of the MOD raw material. Because this reaction occurs in parallel with the esterification reaction of the sol-gel raw material that coexists in the solution, a network including the sol-gel raw material and the MOD raw material is formed through the polycarboxylic acid. Accordingly, the MOD raw material can be efficiently mixed in the polymer chain of the sol-gel raw material. As a result, the crystallization temperature can be further lowered. Moreover, in the raw material solution of the present embodiment, the sol-gel raw material and the MOD raw material are adjusted to the stoichiometric composition of the complex oxide, respectively, and the element A (Pb, Ba, Mg, Ca, Sr, La, Bi, etc.) can be included by 5-25 mol % in excess against the element B (Zr, Ti, Mn, Nb, Ta, V, W etc.). The metal of the element A evaporates easily in the process of crystallization, compared with the metal of the element B. For example, during a heat treatment of a coated film formed by using the raw material solution, Pb readily bonds with oxygen, and may form PbO that has a high vapor pressure, and may volatilize. For this reason, by adjusting the raw material solutions such that the elements that would readily volatilize are included excessively against the stoichiometric composition of a desired ferroelectric film, the shortfall in the crystallization process can be supplemented.

In the raw material solution of the present embodiment, the aforementioned ferroelectric may preferably include Pb as the element A, and Zr and Ti as the element B (PZT), and more preferably Pb as the element A, and Zr, Ti and Nb as the element B (PZTN). In this case, the element B may preferably include Nb in the range from 0.05 mol % to less than 1 mol %, and more preferably, from 0.1 mol % to less than 0.3 mol % to the total amount of Zr and Ti.

Because Nb has generally the same size as that of Ti (ionic radii are close to each other and atomic radii are identical), and weighs two times, it is hard for atoms to slip out the lattice even by collision among atoms by lattice vibration. Further, the valence of Nb is +5, which is stable. Therefore, even if Pb slips out, the valence resulting from the vacated Pb can be supplemented by Nb⁵⁺. Also, even if a Pb vacancy occurs at the time of crystallization, it is easier for Nb having a small size to enter than O having a larger size to slip out.

Furthermore, Nb may also have a valence of +4, such that Nb can sufficiently substitute for Ti⁴⁺. Moreover, Nb has in effect a very strong covalent bond, and it is believed that Pb is also difficult to slip out (H. Miyazawa, E. Natori, S. Miyashita; Jpn. J. Appl. Phys. 39 (2000) 5679).

Because the ferroelectric, and PZTN in particular, obtained with the precursor composition of the present embodiment includes Nb by a specific proportion, adverse effects by the Pb vacancy are canceled, and excellent composition controllability can be obtained.

In the raw material solution of the present embodiment, Si or Ge can be further included. The amount of Si or Ge to be added may preferably be 0.5 mol % or greater, and more preferably 0.5 mol % or greater but less than 5 mol %. As a result, the crystallization energy can be further lowered. Si or Ge may be added in the raw material solution through adding an oxide containing Si or Ge as its constituting element, or by adding an oxide containing Si and Ge as its constituting elements. PbSiO system (Pb₅Si₃O_{X}, Pb₂Si₁O_{X}), PbGeO system (Pb₅Ge₃O_{X}, Pb₂Ge₁O_{X}), BiSiO system (Bi₄Si₃O_{X}, Bi₂Si₁O_{X}), BiGeO system (Bi₄Ge₃O_{X}, Bi₂Si₁O_{X}), and ZrGeO_{X}, HfGeO_{X}, VGeO_{X}, WGeO_{X}, VSiO_{X}, WSiO_{X}, etc. are enumerated as such oxides.

According to the raw material solution of the present embodiment, when a ferroelectric film is formed by using this raw material solution, the crystallization temperature can be lowered in its crystallization. First, the sol-gel raw material that has a network similar to a perovskite structure is fixed to the substrate at a low temperature, in other words, initial nucleuses are formed. It is believed that the MOD raw material with a high degree of freedom supplies required crystal constituting elements on the nucleuses during the crystallization process, such that crystallization can be advantageously thermodynamically advanced. As a result, according to the raw material solution of the present embodiment, mix-mounting of ferroelectric memories, other semiconductor elements such as CMOS circuits, and devices having ferroelectric films can be realized.

Moreover, by using the raw material solution of the present embodiment, a ferroelectric film having an excellent surface morphology in which minute crystals are uniformly distributed can be obtained. It is believed that the above occurs because the sol-gel raw material is mixed with the MOD raw material, the density of initial nucleuses generated rises due to crystallization of the sol-gel raw material, and the MOD raw material is crystallized while filling gaps along with the crystallization.

### EMBODIMENT EXAMPLES

Embodiment examples in accordance with the present invention are described below.

### Embodiment Example 1

In the present embodiment example, first, a sol-gel raw material and a MOD raw material adjusted to the stoichiometric composition of PZT (Zr/Ti=20/80), respectively, were prepared. They were mixed to obtain a raw material solution in accordance with the present embodiment example.

In the present embodiment example, five kinds of raw material solutions with different mixing molar ratios of the sol-gel raw material and the MOD raw material were prepared. The molar ratio of the MOD raw material to the sol-gel raw material in each of the raw material solutions is shown below.

| | |
|---|---|
| Raw material solution 1 | 0.9:0.1 |
| Raw material solution 2 | 0.7:0.3 |
| Raw material solution 3 | 0.5:0.5 |
| Raw material solution 4 | 0.3:0.7 |
| Raw material solution 5 | 0.1:0.9 |

### Embodiment Example 2

In the present embodiment example, first, a sol-gel raw material and a MOD raw material adjusted to the stoichiometric composition of PZT (Zr/Ti=20/80), respectively, were prepared. They were mixed with dimethyl succinate as polycarboxylic acid ester, and n-buthanol as organic solvent to obtain a raw material solution in accordance with the present embodiment example. In the present embodiment example, five kinds of raw material solutions 1-5 with different mixing molar ratios of the sol-gel raw material and the MOD raw material were prepared. The molar ratios of the MOD raw material to the sol-gel raw material were the same as those of the raw material solution of Embodiment Example 1.

### Comparison Example

In the comparison example, only a raw material solution composed of a sol-gel raw material adjusted to the stoichiometric composition of PZT (Zr/Ti=20/80) was prepared.

By using the raw material solutions in accordance with Embodiment Examples 1 and 2 and Comparison Example, a process of coating each of them on a substrate coated with Pt with a <111> orientation by a spin coat method (at 3000 rmp, for 30 seconds) and pre-sintering them at 300° C. for 4 minutes was repeated three times, whereby a coated film of a film thickness of 150 nm was obtained. Then, this coated film was sintered for 30 minutes at 450° C., whereby a PZT thin film was obtained. In this temperature elevation process, the temperature elevation rate was set to be 50° C./sec. to prevent non-ferroelectric phase from growing.

Evaluation of the PZT films thus obtained was conducted as follows.

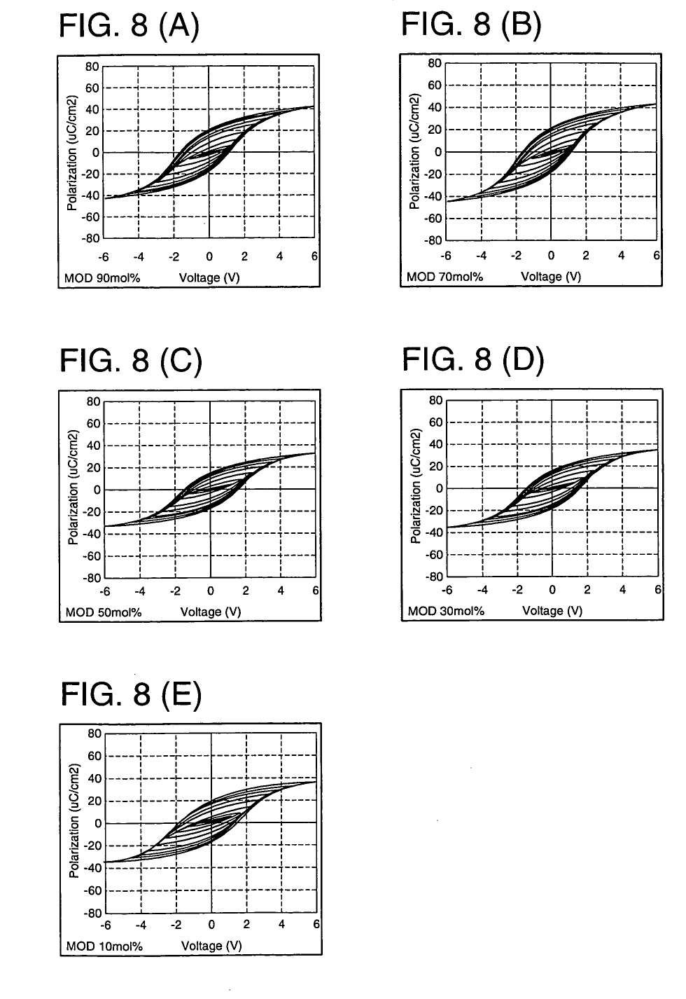

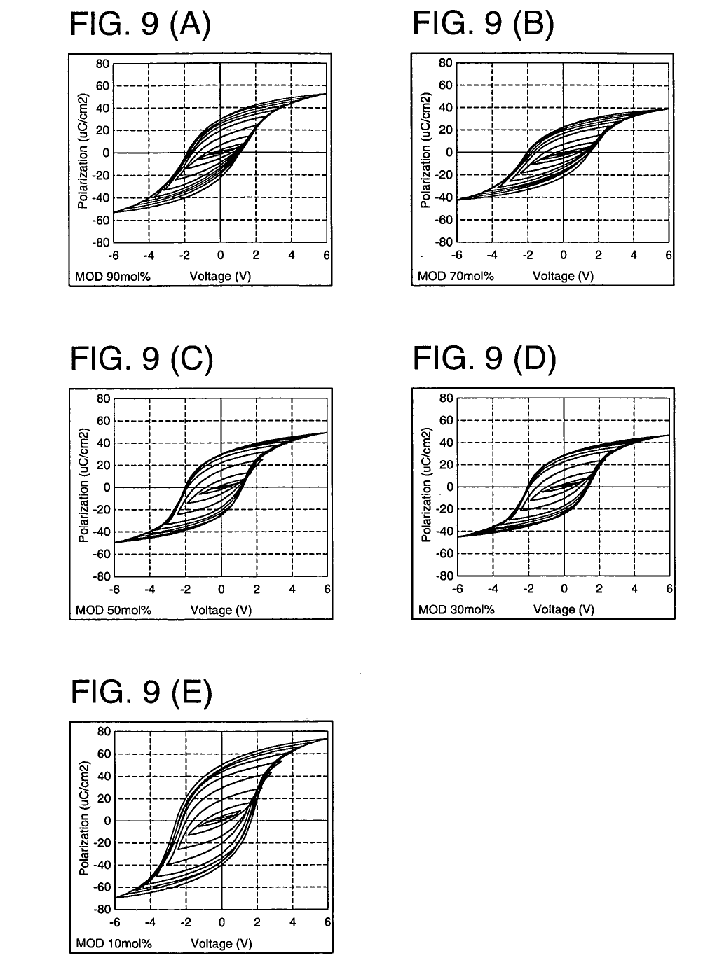

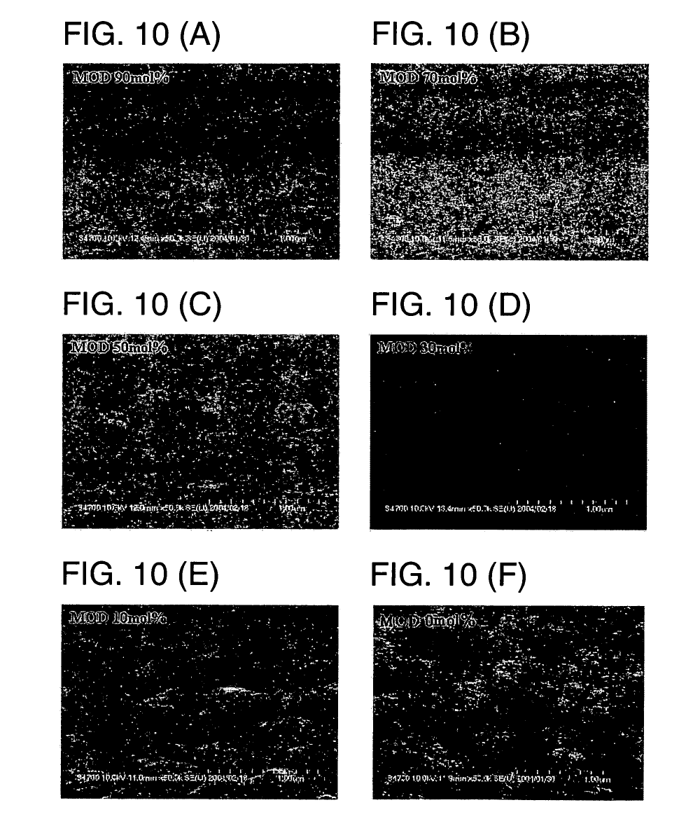

FIG. 7 is a graph indicating the hysteresis characteristic of the PZT film formed by using the raw material solution of Comparison Example. FIGS. 8(A)-(E) are graphs indicting the hysteresis characteristics of the PZT films formed by using the raw material solutions 1-5 of Embodiment Example 1. FIG. 8(A) indicates the hysteresis characteristic of the PZT film formed by using the raw material solution 1, FIG. 8(B) indicates that of the raw material solution 2, FIG. 8(C) indicates that of the raw material solution 3, FIG. 8(D) indicates that of the raw material solution 4, and FIG. 8(E) indicates that of the raw material solution 5. Relations between the symbols at figures and the raw material solutions are the same as the above in FIGS. 9 and 10. As observed from FIG. 8(A)-FIG. 8(E), it was confirmed that each of the films had an adequate polarization characteristic. In addition, it is observed that the hysteresis curves of FIG. 8 are more open than the hysteresis curve of FIG. 7.

FIGS. 9(A)-(E) are graphs indicating hysteresis characteristics of the PZT films formed by using the raw material solutions of Embodiment Example 2. It was confirmed that each of the films had an adequate polarization characteristic similar to those shown FIG. 8. Moreover, it is observed that the hysteresis curves shown in FIG. 9 are more open than the hysteresis curve shown in FIG. 8. In other words, it was affirmed that the PZT films were formed with an excellent squareness. It is believed that this occurred because dimethyl succinate was added in the raw material solution, the affinity between the sol-gel raw material and the MOD raw material was improved, and controllability of the orientation was improved.

FIGS. 10(A)-(F) are SEM images that show the surface morphology of the PZT films formed by using the raw material solutions of Embodiment Example 2 and Comparison Example. FIGS. 10(A)-(E) are SEM images of the PZT films of Embodiment Example 2, and FIG. 10(F) is a SEM image of the PZT film of Comparison Example. As shown in (A)-(E), it can be observed that crystal grains grew even when crystallization occurs at 450° C.

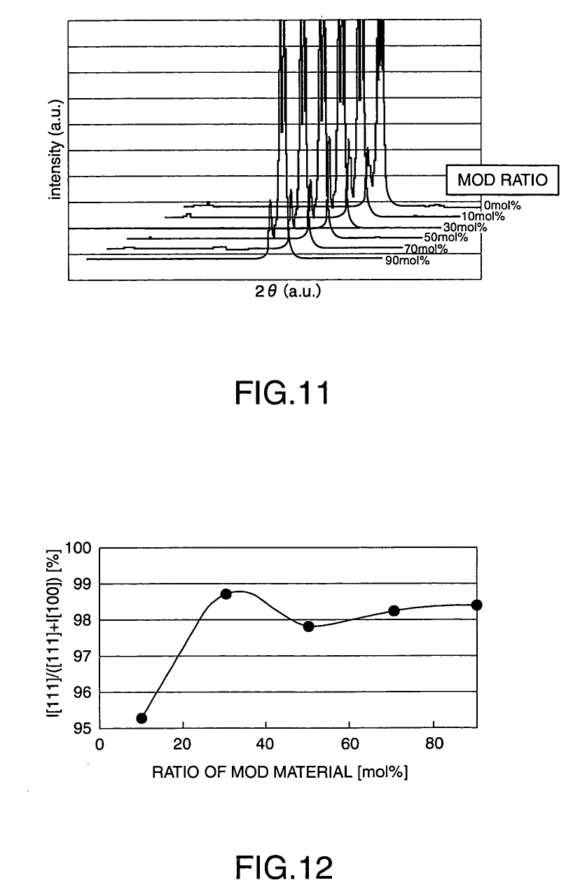

FIG. 11 is a graph showing X-ray diffraction patterns of the PZT films formed by using the raw material solutions of Embodiment Example 2 and Comparison Example. Each of the films exhibited a peak indicating a <111> orientation, and it was confirmed that each of the films had a <111> orientation. Moreover, compared with the X-ray diffraction pattern of Comparison Example, the peak of the <111> orientation of Embodiment Example 2 had a greater intensity, and it was confirmed that the <111> orientation property is stronger.

FIG. 12 is a graph showing the ratio (mol %) of the MOD raw material along the axis of ordinates, and the orientation ratio along the axis of abscissas, which indicates the relation between the ratio of MOD raw material to the orientation ratio. It is observed from FIG. 12 that the orientation ratio rises when the MOD raw material is mixed with the sol-gel raw material. Also, it was affirmed that the orientation ratio improved particularly when it was 30-40 mol %.

According to the raw material solution in accordance with the present embodiment as described above, it was confirmed that ferroelectric films having excellent electrical characteristics and surface morphology can be formed even when crystallization takes place at low temperatures.

2. Ferroelectric Film and Method for Manufacturing Ferroelectric Film

Next, a method for manufacturing ferroelectric films and ferroelectric films are described.

In the manufacturing method in accordance with the present embodiment, a coated film is formed by using the raw material solution described in Section 1 above on a given base substrate. For example, a spin coat method, a dipping method, an LSMCD method, and the like can be enumerated as the method of forming the coated film. Next, the obtained coated film is dried and pre-sintered. Then, by heat-treating the coated film to thereby crystallize the coated film, a ferroelectric film is formed. It is desirable that this heat-treatment is conducted by a rapid heat-treatment with the temperature elevation rate at 50° C./sec. or greater. The heat-treatment at this temperature elevation rate gives an advantage in that the orientation can be controlled excellently.

The ferroelectric film in accordance with the present embodiment is formed by using the raw material solution described in Section 1. Therefore, the ferroelectric film that can be crystallized at low temperatures, whose orientation is controlled, and whose surface morphology is excellent can be provided.

3. Semiconductor Element

Next, semiconductor elements including ferroelectric films formed by using the raw material solution in accordance with the present embodiment are described. In the present embodiment, a ferroelectric memory device including a ferroelectric capacitor that is an example of a semiconductor element is described as an example.

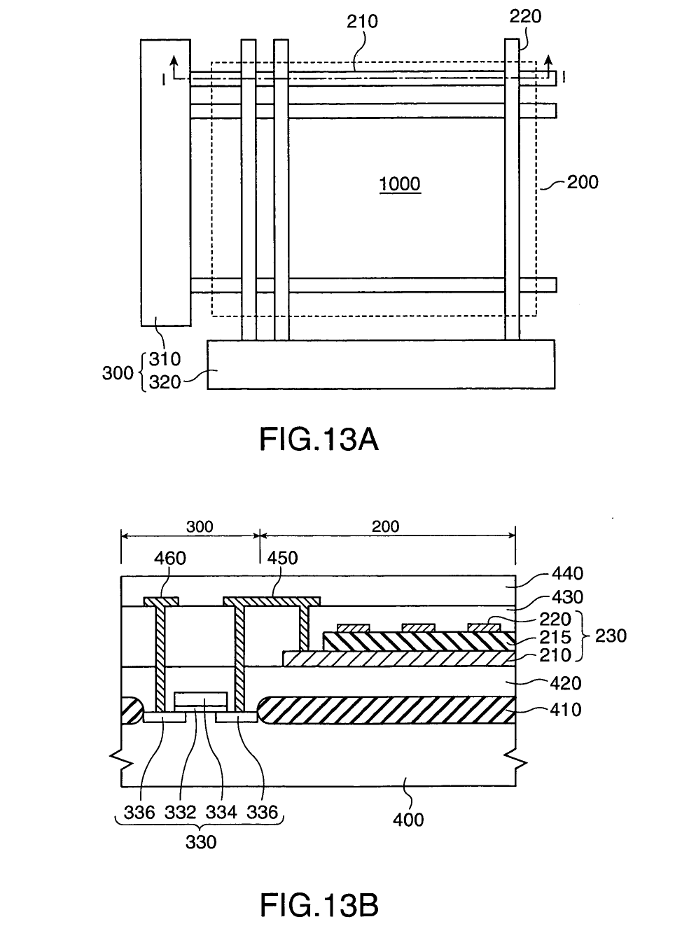

FIGS. 13(A) and 13(B) are views schematically showing a ferroelectric memory device 1000 that uses a ferroelectric capacitor obtained by the manufacturing method in accordance with the present embodiment described above. FIG. 13(A) is a plane configuration of the ferroelectric memory device 1000, and FIG. 13(B) is a cross-sectional view taken along a line I-I in FIG. 13(A).

The ferroelectric memory device 1000 has a memory cell array 200 and a peripheral circuit section 300, as shown in FIG. 13(A). Further, the memory cell array 200 and the peripheral circuit section 300 are formed in different layers, respectively. The peripheral circuit section 300 is formed on a semiconductor substrate 400 in an area that is different from the memory cell array 200. As a concrete example of the peripheral circuit section 300, a Y-gate, a sense amplifier, an I/O buffer, an X-address decoder, a Y-address decoder, or an address buffer can be enumerated.

The memory cell array 200 includes lower electrodes (word lines) 210 for selection of rows, and upper electrodes (bit lines) 220 for selection of columns, which are disposed orthogonal to one another. Also, the lower electrodes 210 and the upper electrodes 220 are arranged in stripes composed of a plurality of line shaped signal electrodes. It is noted that the signal electrodes can be formed such that the lower electrodes 210 may be bit lines, and the upper electrodes 220 may be word lines.

Then, as shown in FIG. 13(B), a ferroelectric film 215 is disposed between the lower electrodes 210 and the upper electrodes 220. In the memory cell array 200, memory cells that function as ferroelectric capacitors 230 are formed in areas where the lower electrodes 210 and the upper electrodes 220 intersect one another. The ferroelectric film 215 is a film formed by using the raw material solution in accordance with the present embodiment described above. It is noted that the ferroelectric film 215 only has to be arranged at least in an area where the lower electrode 210 and the upper electrode 220 intersect each other.

Further, the ferroelectric memory device 1000 includes a second interlayer insulation film 430 formed to cover the lower electrodes 210, the ferroelectric film 215, and the upper electrodes 220. In addition, an insulating protection layer 440 is formed on the second interlayer insulation film 430 to cover wring layers 450 and 460.

The peripheral circuit section 300 includes various circuits that selectively write or read information in and from the above-described memory cell array 200 shown in FIG. 13(A). For example, the peripheral circuit section 300 includes a first driving circuit 310 to control the lower electrodes 210 selectively, a second driving circuit 320 to control the upper electrodes 220 selectively, and a signal detection circuit such as a sense amplifier (omitted in the figure).

Also, the peripheral circuit section 300 includes MOS transistors 330 formed on the semiconductor substrate 400, as shown in FIG. 13(B). The MOS transistor 330 has a gate insulation layer 332, a gate electrode 334, and source/drain regions 336. The MOS transistors 330 are isolated from one another by an element isolation area 410. The first interlayer insulation layer 420 is formed on the semiconductor substrate 400 on which the MOS transistor 330 is formed. Further, the peripheral circuit section 300 and the memory cell array 200 are electrically connected to one another by a wiring layer 51.

Next, an example of writing and reading operations in the ferroelectric memory device 1000 is described.

First, in the reading operation, a read voltage is impressed to a capacitor of a selected memory cell. This serves as a writing operation to write ‘0’ at the same time. At this moment, a current that flows on a selected bit line or a potential on the bit line when it is brought to high impedance is read by a sense amplifier. At this moment, a predetermined voltage is impressed to capacitors of non-selected memory cells to prevent cross-talk at the time of reading.

In the writing operation, when writing ‘1,’ a voltage that inverts the polarization of a capacitor is impressed to a capacitor of a selected cell. When writing ‘0,’ a voltage that does not invert the polarization of a capacitor is impressed to a capacitor of a selected cell, to retain the “0” state written at the time of reading operation. At this moment, a predetermined voltage is impressed to capacitors of non-selected cells to prevent cross-talk at the time of writing.

In the ferroelectric memory device 1000, the ferroelectric capacitor 230 has the ferroelectric film 215 that can be crystallized at low temperatures. Therefore, there is an advantage in that the ferroelectric memory device 1000 can be manufactured without deteriorating the MOS transistors 330 and the like that compose the peripheral circuit 300. Moreover, because the ferroelectric capacitor 230 has an excellent hysteresis characteristic, a highly reliable ferroelectric memory device 1000 can be provided.

4. Piezoelectric Element

Next, an example in which a ferroelectric film formed by using the raw material solution in accordance with the present embodiment is applied to a piezoelectric element is described.

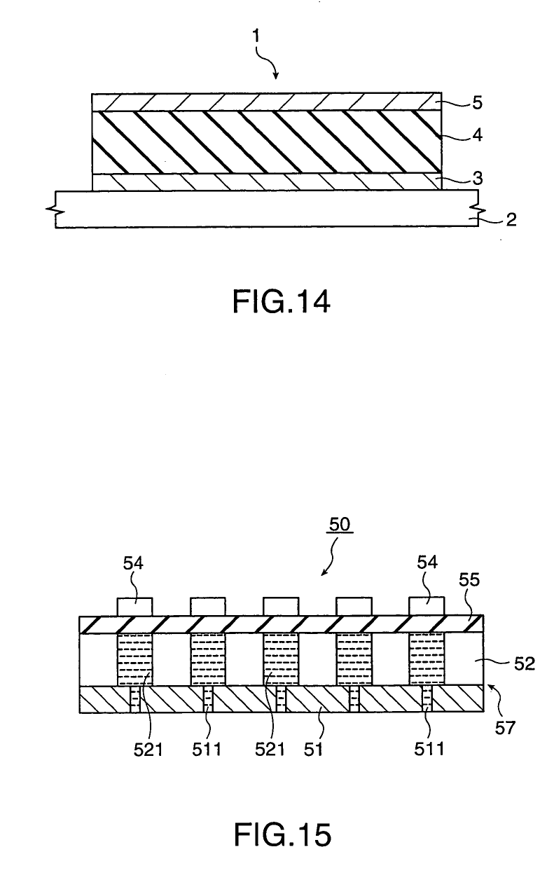

FIG. 14 is a cross-sectional view showing a piezoelectric element 1 that has a ferroelectric film formed by using the raw material solution of the present invention. The piezoelectric element 1 includes a substrate 2, a lower electrode 3 formed on the substrate 2, a piezoelectric layer 4 formed on the lower electrode 3, and an upper electrode 5 formed on the piezoelectric layer 4.

As the substrate 2, for example, a silicon substrate can be used. In the present embodiment, a single-crystal silicon substrate with a (110) orientation is used. Also, as the substrate 2, a single-crystal silicon substrate with a (100) orientation, or a single-crystal silicon substrate with a (111) orientation can be used. Also, as the substrate 2, a substrate in which a thermal oxidation film or an amorphous silicon oxide film that is a natural oxidation film is formed on the surface of a silicon substrate can be used. By processing the substrate 2, it can have ink cavities 521 in an ink jet recording head 50 as described below (see FIG. 15).

The lower electrode 3 becomes to be one of electrodes for applying a voltage to the piezoelectric layer 4. The lower electrode 3 can be formed, for example, in the same plane configuration as that of the piezoelectric layer 4. It is noted that, when multiple piezoelectric elements 1 are formed on an ink jet recording head 50 to be described below (see FIG. 15), the lower electrode 3 can be formed to function as a common electrode for each of the piezoelectric elements 1. The lower electrode 3 may be formed to a film thickness, for example, of the about 100 nm-200 nm.

The piezoelectric layer 4 is a layer formed by using the raw material solution in accordance with the present embodiment described above, and has a perovskite type structure.

The upper electrode 5 can be formed by, for example, a sputter method, a vacuum deposition method, or the like. The upper electrode 5 is formed of, for example, Pt (platinum). It is noted that the material of the upper electrode 5 is not limited to Pt, but, for example, Ir (iridium), IrOₓ (iridium oxide), Ti (titanium), SrRuO₃ or the like can also be used.

Because the piezoelectric element of the present embodiment is formed by using the raw material solution in accordance with the present embodiment described above, the piezoelectric layer can be crystallized at low temperatures, and mixed mounting with other semiconductor elements can be achieved.

5. Inkjet Recording Head and Inkjet Printer

Next, an inkjet recording head in which the above-described piezoelectric element functions as a piezoelectric actuator, and an inkjet printer having the inkjet recording head are described.

In the following description, the inkjet recording head is first described, and then the inkjet printer is described.

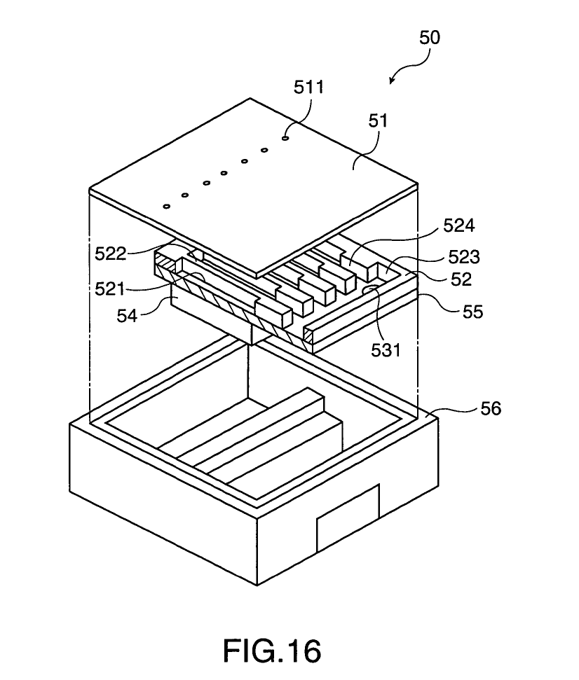

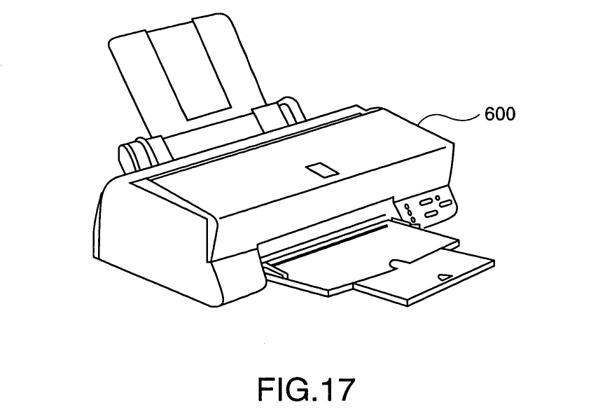

FIG. 15 is a side cross-sectional view schematically showing a structure of the inkjet recording head in accordance with the present embodiment, and FIG. 16 is an exploded perspective view of the inkjet recording head, which shows the head upside down with respect to a state in which it is normally used. FIG. 17 shows an ink jet printer 600 that has the inkjet recording head in accordance with the present embodiment.

5.1 Ink Jet Recording Head

As shown in FIG. 15, the inkjet recording head 50 is equipped with a head main body (base body) 57 and piezoelectric sections 54 formed on the head may body 57. The piezoelectric section 54 is provided with a piezoelectric element 1, and the piezoelectric element 1 is composed of a lower electrode 3, a piezoelectric film (ferroelectric film) 4 and an upper electrode 5 successively stacked in layers. The piezoelectric film 4 is a film that is formed by using the raw material solution described in Section 1 above. The piezoelectric section 54 functions as a piezoelectric actuator in the inkjet recording head. The piezoelectric actuator is an element that has the function to move a certain substance.

The inkjet recording head 50 includes a nozzle plate 51, an ink chamber substrate 52, an elastic film 55, and piezoelectric sections 54 that are bonded to the elastic film 55, which are housed in a housing 56. The inkjet recording head 50 forms an on-demand type piezoelectric head.

The nozzle plate 51 is formed from, for example, a rolled plate of stainless steel or the like, and includes multiple nozzles 511 formed in a row for jetting ink droplets. The pitch of the nozzles 511 may be appropriately set according to the printing resolution.

The ink chamber substrate 52 is fixedly bonded (affixed) to the nozzle plate 51. The ink chamber substrate 52 has a plurality of cavities (ink cavities) 521, a reservoir 523, and supply ports 524, which are defined by the nozzle plate 51, side walls (partition walls) 522 and the elastic film 55. The reservoir 523 temporarily reserves ink that is supplied from an ink cartridge (not shown). The supply ports 524 supply the ink from the reservoir 523 to the respective cavities 521.

Each of the cavities 521 is disposed for each of the corresponding nozzles 511 as shown in FIG. 15 and FIG. 16. Each of the cavities 521 has a volume that is variable by vibrations of the elastic film 55. The cavities 521 are formed to eject ink by the volume change.

As a base material for obtaining the ink chamber substrate 52, a silicon single-crystal substrate with a (110) orientation is used. Because the silicon single-crystal substrate with a (110) orientation is suitable for anisotropic etching, the ink chamber substrate 52 can be readily and securely formed. It is noted that this silicon single-crystal substrate is used with its surface where the elastic film 55 is formed being a (110) surface.

The elastic film 55 is disposed on the ink chamber substrate 52 on the opposite side of the nozzle plate 51, and a plurality of piezoelectric sections 54 are provided on the elastic film 55 on the opposite side of the ink chamber substrate 52. A communication hole 531 that penetrates the elastic film 55 in its thickness direction is formed in the elastic film 55 at a predetermined position. Ink can be supplied from an ink cartridge to the reservoir 523 through the communication hole 531.

Each of the piezoelectric sections 54 is electrically connected to a piezoelectric element driving circuit (not shown), and is structured to operate (vibrate, deform) based on signals of the piezoelectric element driving circuit. In other words, each of the piezoelectric sections 54 functions as a vibration source (head actuator). The elastic film 55 vibrates (deforms) by vibrations (deformation) of the piezoelectric section 54, and functions to instantaneously increase the inner pressure of the cavity 521.

Although an ink jet recording head that jets ink is described above as one example, the present embodiment is intended to be generally applied to all liquid jet heads and liquid jet devices that use piezoelectric elements. As the liquid jet head, for example, a recording head used for an image recording device such as a printer, a color material jet head used to manufacture color filters of liquid crystal displays, etc., an electrode raw material jet head used for forming electrodes of organic EL displays, FED (plane emission display), etc., a bio-organic material jet head used for manufacturing biochips, and the like can be enumerated.

Also, the piezoelectric element in accordance with the present embodiment can be applied, without being particularly limited to the application examples described above, to a variety of modes such as piezoelectric pumps, surface acoustic wave elements, thin film piezoelectric resonators, frequency filters, oscillators (for example, voltage control SAW oscillators) and the like.

1. A raw material solution to form ferroelectric shown by a general formula of ABO₃, the raw material solution comprising:
a sol-gel raw material; and
a MOD raw material having a stoichiometric composition of at least an element B that is identical with the sol-gel raw material.

2. A raw material solution according to claim 1, wherein the content of the MOD raw material is 10-50 mol % against the total amount of the sol-gel raw material and the MOD raw material.

3. A raw material solution according to claim 1, wherein the content of the MOD raw material is 30-40 mol % against the total amount of the sol-gel raw material and the MOD raw material.

4. A raw material solution according to claim 1, comprising a material that can improve affinity between the sol-gel raw material and the MOD raw material.

5. A raw material solution according to claim 4, wherein the material undergoes an esterification reaction with at least one of the sol-gel raw material and the MOD raw material.

6. A raw material solution according to claim 4, wherein the material is polycarboxylic acid or polycarboxylic acid ester.

7. A raw material solution according to claim 1, comprising alcohols as an organic solvent.

8. A raw material solution according to claim 1, comprising a simple perovskite structure.

9. A raw material solution according to claim 1, wherein an element A comprises at least one of Pb, Ba, Mg, Ca, Sr, La and Bi, and an element B comprises at least one of Zr, Ti, Mn, Nb, Ta, V and W.

10. A raw material solution according to claim 9, wherein the element A is included by 5-25 mol % in excess against the element B.

11. A raw material solution according to claim 9, further comprising Si or Ge added therein.

12. A raw material solution according to claim 11, wherein the Si or Ge is added as an organic metal or a metal alkoxide.

13. A ferroelectric film formed by using the raw material solution according to claim 1.

14. A method for manufacturing a ferroelectric film, comprising:
a step of coating the raw material solution according to claim 1 on a substrate;
a step of performing drying and calcinating of the coated film; and
a step of performing crystallization of the coated film by a heat treatment.

15. A method for manufacturing a ferroelectric film according to claim 14, wherein the crystallization is conducted by a rapid heat treatment at a heat elevation rate of 50° C./sec. or greater.

16. A piezoelectric element using the ferroelectric film according to claim 13.

17. A semiconductor element using the ferroelectric film according to claim 13.

18. A piezoelectric actuator using the piezoelectric element according to claim 16.

19. An ink jet recording head using the piezoelectric actuator according to claim 18.

20. An ink jet printer using the ink jet recording head according to claim 19.
